(19) United States
(12) Patent Application Publication
(10) Pub. No.: US 2026/0118202 A1
(43) Pub. Date: Apr. 30, 2026

(54) RACK LEVEL OPTICAL LEAK DETECTION USING A CAMERA

(71) Applicant: DELL PRODUCTS L.P., Round Rock, TX (US)

(72) Inventors: Michael Stumpf, Cedar Park, TX (US); Sandor Farkas, Round Rock, TX (US)

(21) Appl. No.: 18/927,390

(22) Filed: Oct. 25, 2024

(51) Int. Cl. G01M 3/20; G06T 7/00; H05K 7/20

(52) U.S. Cl. CPC G01M 3/20; G06T 7/0008; H05K 7/20218; G06T 2207/10064; G06T 2207/20041

(57) ABSTRACT

An information handling system may include a coolant detection system to identify the presence of a leak in a liquid cooling system. The coolant detection system may initially set a timing and duration of an ultraviolet (UV) light to illuminate the liquid cooling system. The coolant detection system may then select at least one image from a plurality of captured images based on the set timing and duration of the UV illumination. The selected at least one image is further processed to enhance a fluorescent color on the image that can be indicative of the leak in the liquid cooling system.

### FIELD OF THE DISCLOSURE

The present disclosure generally relates to information handling systems and, more particularly, relates to liquid coolant leak detection in an information handling system.

### BACKGROUND

As the value and use of information continue to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use, such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

An information handling system may include a liquid cooling system and a coolant detection system that can detect a leak in the liquid cooling system. The liquid cooling system may circulate a coolant liquid to components of the information handling system. This coolant liquid may include a fluorescent dye or a coolant mixture that emits light at a particular wavelength when illuminated by an ultraviolet (UV) light. On the other hand, the coolant detection system may include a controller (or processor), a UV light source, and a camera that is configured to capture images (also referred to as image frames) of an object, such as the liquid cooling system. In some embodiments, the controller operates to set a timing and duration of firing a UV light from the UV light source. Further, the controller operates to receive images from the camera, process the received images, and identify distinct features that are representative of the leak. For example, the controller may select at least one image from the received images based on the timing and duration of the UV light. The controller may then stretch the selected at least one image to a rectilinear grid, and further perform blurring, down-sampling, and applying a threshold to enhance fluorescent color in the selected at least one image. The enhanced fluorescent color at a particular emission spectrum may be used to determine the presence and location of the leak.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIGS. 1-2 are block diagrams of an information handling system according to at least one embodiment of the present disclosure;

FIG. 3 is a block diagram of a captured image according to at least one embodiment of the present disclosure;

FIG. 4 is a block diagram of an image processing according to at least one embodiment of the present disclosure;

FIG. 5 is a block diagram of captured images at a particular camera frame rate according to at least one embodiment of the present disclosure;

FIG. 6 is a flow diagram of a method for using a camera to identify a leak in a liquid cooling system according to at least one embodiment of the present disclosure; and

FIG. 7 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

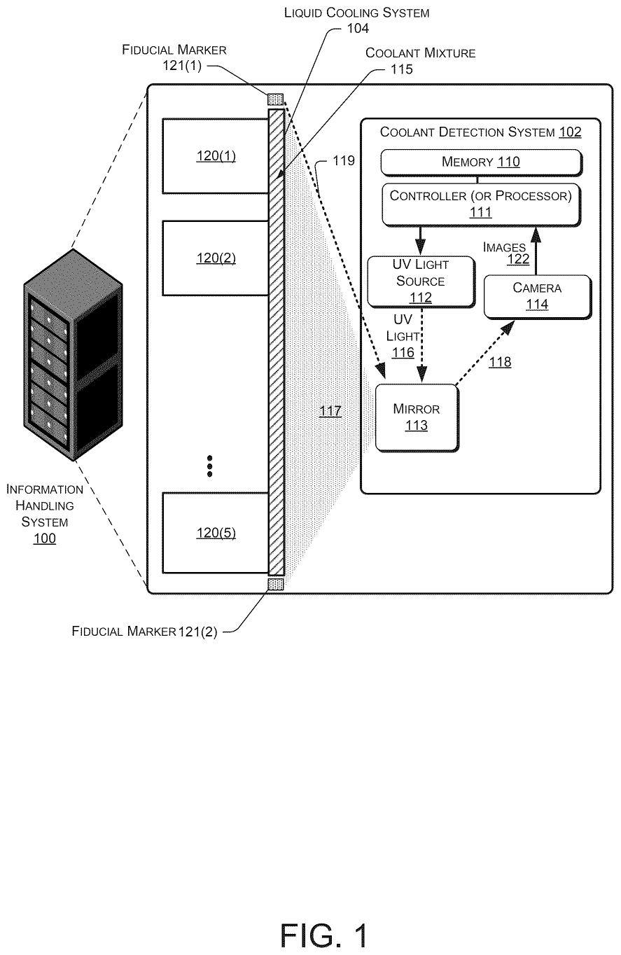

FIG. 1 illustrates an information handling system 100 including a coolant detection system 102 and a liquid cooling system 104, according to at least one embodiment of the present disclosure. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, the information handling system 100 may represent a computer system, such as a laptop computer, a desktop computer, a computer workstation, a server system, a blade server system, or other rack-mounted computer equipment, such as a storage server, a network server, a network switch/router, or other datacenter computer equipment, or other electronic equipment generally defined.

Information handling system 100 may be characterized as including the coolant detection system 102 to detect a leak (not shown) in the liquid cooling system 104 via the use of a camera 114. In a particular embodiment, coolant detection system 102 may set a timing and duration of a UV light 116 when capturing images 122 of the liquid cooling system 104. The coolant detection system 102 may process the captured images 122 by selecting at least one image based on the set timing and duration of the UV light 116. The coolant detection system 102 may then perform a stretching of the selected at least one image to a rectilinear grid, blurring of the stretched image, down-sampling of the blurred image, and applying of a threshold to enhance any fluorescent colors in the down-sampled blurred image. The selective processing of captured images saves controller processing time in detecting the fluorescent color that is indicative of the presence and location of the leak.

In an embodiment, the coolant detection system 102 may include, without limitation, a memory 110, a controller (or processor) 111, a UV light source 112, a mirror 113, and the camera 114. In certain examples, the mirror 113 may be any combination of multiple mirrors without varying from the scope of this disclosure. The camera 114 may utilize the mirror 113 to capture a portion or an entire scene, such as the liquid cooling system 104. The various elements of the coolant detection system 102 may be understood to be contained within the information handling system 100, or one or more of the elements of the coolant detection system 102 may be understood to be external to the information handling system, as needed or desired.

The liquid cooling system 104 may represent various cooling headers, heat exchangers, coolant pumps, controllers, piping, and coolant routing elements, such as coolant tubes, pipes, fittings, and the like, coolant reservoirs, or other elements that may be typically associated with a liquid cooling system. The various elements of the liquid cooling system 104 may be understood to be contained within information handling system 100, or one or more of the elements of the liquid cooling system may be understood to be external to the information handling system, as needed or desired.

In an embodiment, the liquid cooling system 104 may use a specialized coolant mixture 115 to transfer heat away from a plurality of installed components 120(1)-120(5). The specialized coolant mixture 115 may include a fluorescent dye (not shown) that emits or reflects a different color wavelength when excited by a beam of UV light 116 from the UV light source 112. In this embodiment, the liquid cooling system 104 may circulate the specialized coolant mixture 115 through heat exchangers (not shown) that are in direct contact with the installed components 120(1)-120(5).

Components 120(1)-120(5) may include hardware components that work together to process or store data. For example, the component can be a processor, memory, storage, network interface card (NIC), motherboard, power supply unit (PSU), and the like. In this example, each component 120(1)-120(5) can be directly connected to the liquid cooling system 104 that is configured to absorb and efficiently transfer heat away from the component.

Memory 110 may store preconfigured locations of the fiducial markers 121(1)-121(2), known or preconfigured locations and dimensions of the components 120(1)-120(5), configurations of the liquid cooling system 104, angle of tilt of the mirror 113, frame rate of the camera 114, configured timing and duration of the UV light 116, and other parameters that can be used to identify the location and position of the leak in the liquid cooling system 104. The memory 110 may also store additional fluorescent based—fiducial markers or signs that can be used as references for determining a particular position, identification, or configuration of the liquid cooling system 104 and/or components 120(1)-120(5). Further, the memory 110 may store captured images 122 from the camera 114, algorithms to use for perspective corrections due to the angle of tilt of the mirror 113, and other parameters that can be used by the controller 111 for video or image processing.

The UV light source 112 may represent a light-emitting diode (LED) or LED array that emits light in a UV spectrum. The UV light includes a light wavelength of about 100 to 400 nanometers. The UV light source 112 can emit sufficient power of UV light 116 to illuminate a particular area in the information handling system 100, and may include a collimating lens, as needed or desired, to generate a narrow beam or a wide beam of UV light 116. The narrow beam or wide beam of UV light 116 may include an amount of divergence or spread of the UV light when illuminating the liquid cooling system 104 including the fiducial markers 121(1)-121(2).

For example, the collimating lens of the UV light source 112 may include a longer focal length and a small diameter to concentrate the UV light 116 to a wider and more spread-out beam. The wider beam of UV light 116 may illuminate, for example, the components 120(1)-120(5) and the liquid cooling system 104 at the same time. In this example, the mirror 113 may reflect 117 the UV light 116 towards the components 120(1)-120(5) and the liquid cooling system 104. The mirror 113 may also relay in the direction of arrow 118 reflected images of the components 120(1)-120(5) and the liquid cooling system 104. The reflected images may include the objects that can be taken or captured given a particular tilt and/or location of the mirror 113.

Each of the fiducial markers 121(1)-121(2) may include a product code or sign that uses a fluorescent dye to emit, in a direction of arrow 119, a different color wavelength when excited by the UV light 116. The fiducial marker can be a fluorescent based-barcode line, a fluorescent based-number, a fluorescent based-letter, or any fluorescent based-material of any shape that can be used as reference points during the image processing as described herein. The fiducial marker can be placed on a particular component, or it can be separately located on other parts of the information handling system 100. For example, the fiducial marker 121(1) may indicate a top surface of the liquid cooling system 104, while the fiducial marker 121(2) can indicate a bottom surface. In this example, the fiducial markers 121(1) and 121(2) need not be placed on the components but can be located in other areas of the information handling system 100. In some embodiments, the fluorescent based-fiducial markers 121(1) and 121(2) are used as references to determine the locations of the components 120(1)-120(5) and the parts of the liquid cooling system 104 in the information handling system 100. These fiducial markers may be masked during the image processing as may be needed or desired.

Camera 114 may represent a Complementary Metal-Oxide-Semiconductor (CMOS) camera or other photographic detector, such as a charge-coupled device (CCD) array or the like, that is configured to capture images within a preconfigured time period or interval. For example, the camera 114 starts capturing images in sync with the firing of the UV light 116. In this example, the camera 114 may capture the fluorescent color reflections (yellowish green) that can indicate the presence of the leak. The camera 114 can be utilized to detect motion of the leaked coolant liquid as the liquid spreads within information handling system 100. Here, controller 111 will be understood to provide greater functionality, such as video image processing of the captured images or image frames to detect the presence of a leak.

For example, the controller 111 operates to initially set the timing and duration of the UV light 116. The timing may include the starting time and ending time for the firing of the UV light 116 to illuminate a scene or object in the information handling system 100. The duration may include an amount of time of the UV light illumination. In some embodiments, the controller 111 may synchronize the timing of firing the UV light 116 with a frame rate (not shown) of the camera 114. For example, the UV light 116 is fired at the start of each frame rate of the camera 114. In other instances, the timing of firing the UV light is not synchronized as desired. When not synchronized, the duration of firing of the UV light 116 is at least twice the width of an image frame at a particular frame rate of the camera 114 to capture at least one whole image of the scene or object.

Following the example above, the controller 111 operates to receive the captured images 122 from the camera 114. The captured images 122 may include a plurality of original images that can be captured by the camera 114 using a particular frame rate, such as 50 frames per second (fps). The original images can undergo perspective corrections to compensate for the tilt and location of the mirror 113. In some embodiments, the controller 111 operates to select only the images that were captured during the firing of the UV light 116. Here, the controller 111 saves processing time by selectively processing only the received images 122 that were taken during the activation of the UV light source 112. For example, the controller 111 may select one or more images from the images 122 based on the set or configured timing and duration of the UV light 116.

With the selected one or more images, the controller 111 operates to stretch the selected one or more images to a rectilinear grid on account of the orientation and location of the mirror 113 relative to the captured scene or object. In this example, the controller 111 operates to stretch the selected images using the fiducial markers 121(1) and 121(2) as references.

Further, the controller 111 operates to mask the fiducial markers at subsequent image processing steps to minimize errors in the detection of the fluorescent colors that are indicative of the leak. For example, the subsequent processing steps include blurring of the stretched images, down-sampling of the blurred images, and applying a threshold to enhance the fluorescent color that may be present in the selected images.

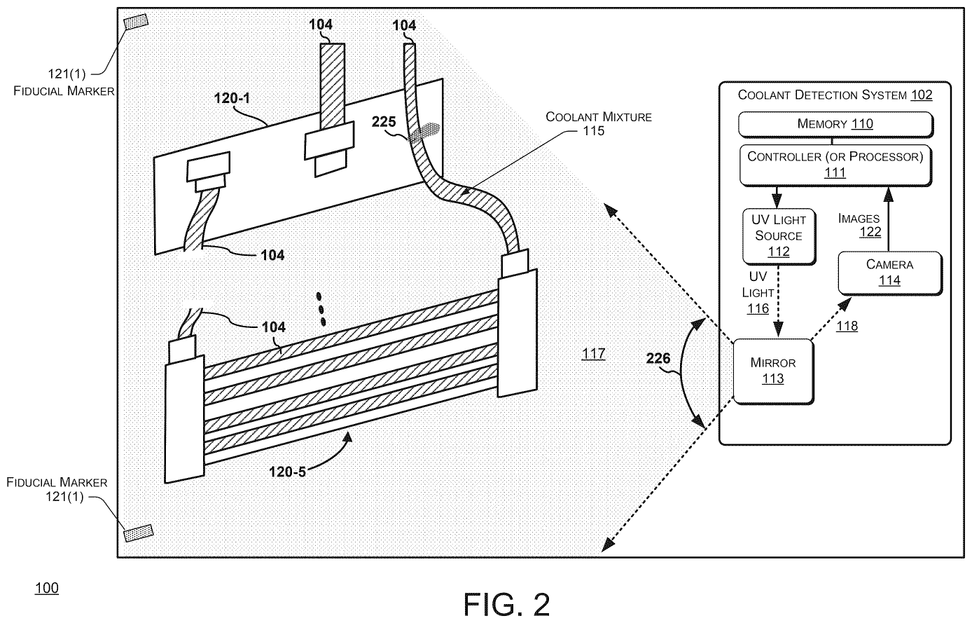

FIG. 2 illustrates the information handling system 100 with a coolant leak 225. The coolant leak 225 can be created when various elements of the liquid cooling system 104 develop pinhole leaks in tubing or piping, when fittings are misaligned or worn out, when heat exchanges or cold plates are misaligned, or via other mechanisms as may occur to permit the coolant mixture 115 to leak from the liquid cooling system 104. As shown, the mirror 113 may be located at the bottom of the information handling system 100 such that the reflection 117 is generated at a certain perspective angle 226 of the mirror 113. The perspective angle 226 may dictate the field of view (FOV) that the camera 114 can capture and record.

For example, the angle 226 is about 90 degrees. In this example, the angular range of 90 degrees may generate a corresponding capture angle of the scene or object to be captured.

The capture angle may include the mirror 113 that is substantially aligned with regard to the component 120(5) but positioned at a certain angle with regard to the component 120-1. Here, the controller 111 performs a perspective correction to correct the tilted view of the component 120(1) relative to the position of the mirror 113.

In some embodiments, a selected image from the images 122 can be adjusted to make it appear as if it were taken with an aligned mirror 113. For example, the camera 114 may transmit the images 122 to the controller 111 for video image processing. In this example, the controller 111 may select one or more images based on the timing and duration of the UV illumination, and process the selected one or more images using a rectilinear grid correction to perform a perspective correction as further described below.

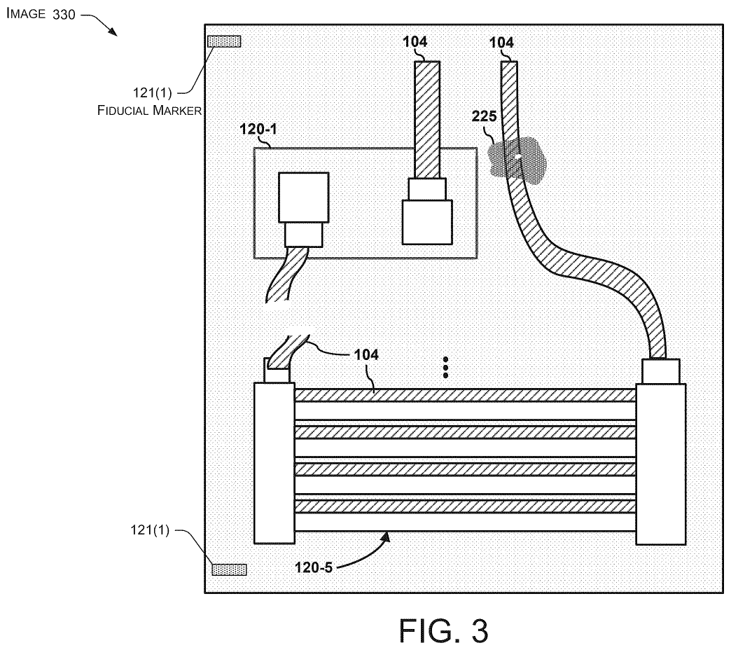

FIG. 3 illustrates an example image 330 that is generated after a perspective correction. In an embodiment, the controller 111 may receive the images 122 from the camera 114, select one or more images based on the timing and duration of the UV light 116, and then perform the rectilinear grid correction on the selected one or more images using fluorescent based - markers.

For example, the controller 111 may utilize the fiducial markers 121(1) and 121(2) as reference points in correcting the selected image to a desired rectilinear grid. The fiducial markers 121(1) and 121(2) may represent two corners or distinctive features of the selected image. In this example, the controller 111 may utilize an algorithm to calculate a matrix based on the identified reference points. This matrix may define the transformation to map the selected image onto the rectilinear grid. The matrix is then applied to the selected image to adjust it into the desired rectilinear perspective.

In some embodiments, the controller 111 may use additional fluorescent based—markers (not shown) on each of the components 120(1)-120(5) to improve the transformation of the selected image. Here, the corrected image 330 may correspond to an image that is captured by a substantially aligned mirror 113 rather than a tilted one. For example, the selected image may initially show a small leak, such as the illustrated leak 225 in FIG. 2, because of the tilted position of the mirror 113. However, upon transformation of the selected image, the adjusted image 330 in FIG. 3 now illustrates a bigger leak 225 that can be easily identified and detected via image processing, as further described below.

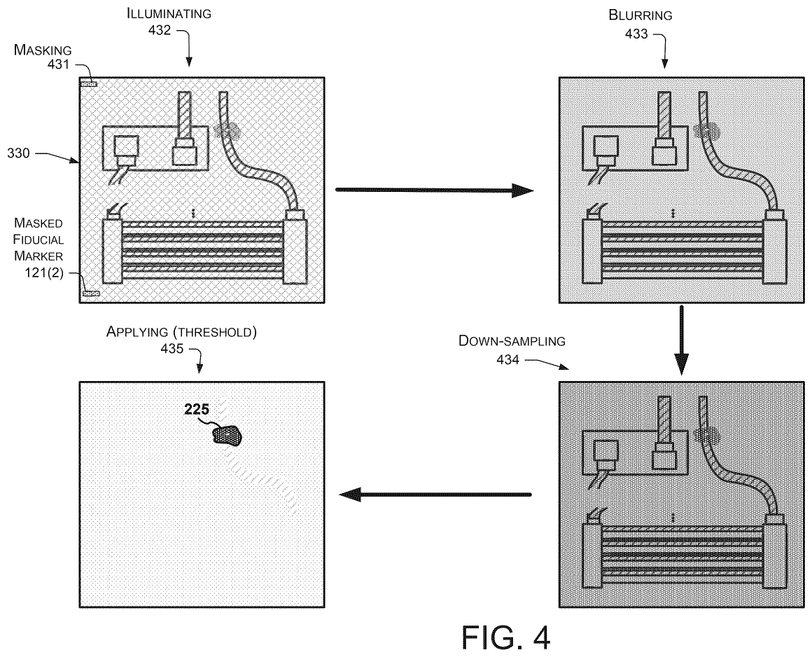

FIG. 4 illustrates an image processing of the corrected image, such as the adjusted image 330 in FIG. 3. FIG. 4 illustrates the additional processing of the corrected image 330 to isolate and identify the presence of the leak 225. Without limitation, the additional processing includes masking 431 of the fiducial markers or any other pre-identified fluorescent based—markers or signs that can generate fluorescent color of a different wavelength during an illuminating 432 with the UV light, blurring 433 of the selected image, down-sampling 434 of the blurred image, and applying 435 of a threshold to enhance the fluorescent color that corresponds to the leak 225.

In an embodiment, the controller 111 may set the timing and duration of illuminating 432 the scene or object, such as the liquid cooling system and components of the information handling system 100. The timing of firing the UV light source 112 may be synchronized with the frame rate of the camera, such as the camera 114 of FIG. 1. For example, the camera 114 includes a frame rate of 50 frames per second (fps). Here, the controller 111 may set the timing of the illuminating 432 to cover the first five frames only. In this example, the controller 111 operates to select the first five frames for further image processing and disregard the rest of the frames (6^{th} to 50^{th} frames) as unwanted signals or images to save processing time.

The controller 111 may then perform perspective corrections using the fiducial markers and other fluorescent based—signs at preconfigured locations in the information handling system 100. After the perspective corrections of the selected images (e.g., the first five frames in the above example), the controller 111 operates to mask (431) the fiducial markers in specific areas of the selected image as represented by the image 330. For example, the controller 111 may retrieve the exact locations of the fiducial markers and other fluorescent based—signs from the memory, such as the memory 110 of FIG. 1. Here, the controller 111 operates to selectively block or mask these regions to minimize error in the determination of the fluorescent colors that are representative of the leak 225.

In some embodiments, the controller 111 operates to perform the blurring 433 of the stretched or corrected image 330 to reduce some detail or obscure specific areas in the corrected image. The blurring 433 may include smoothing of the edges of the image by averaging the colors of neighboring pixels. For example, the controller 111 may identify specific regions of the image 330 to blur while keeping other areas sharp. In this example, the blurring 433 may be particularly applied to the identified regions of the image 330. After blurring, the controller 111 further operates to perform the down-sampling 434 to reduce the overall size of the image 330 while maintaining its aspect ratio. As compared to the blurring 433, the blurring reduces detail and sharpness, while the down-sampling 434 may reduce the number of pixels.

In some embodiments, controller 111 operates to perform the applying 435 of the thresholds to enhance the fluorescent colors that may indicate the presence of the leak 225. The process of thresholding may include converting a grayscale image into a binary image (black and white) by setting a pixel intensity threshold, and the pixels that are above or below this pixel intensity threshold are assigned new values. For example, new values of “ones” correspond to pixel's intensities that are greater than or equal to the threshold, while zero values correspond to the pixel's intensities that are less than the threshold. The zero and one values may create the binary image, which includes an enhanced image of the leak 225.

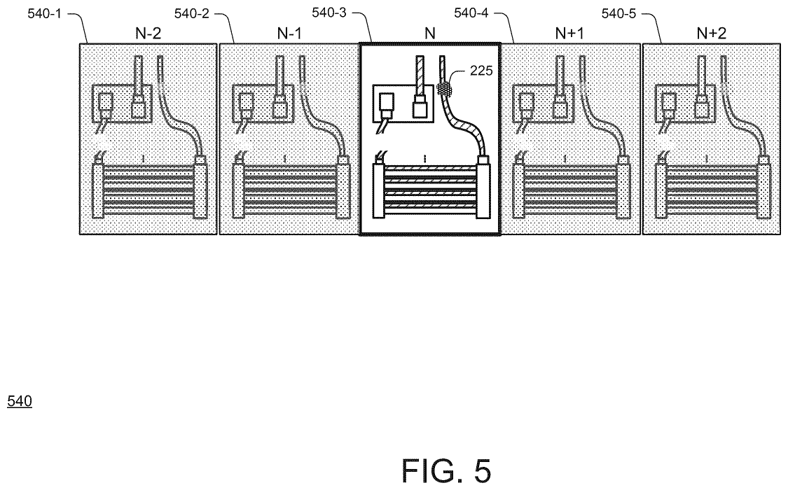

FIG. 5 illustrates multiple image frames 540 that the controller 111 may receive from the camera 114. For illustration purposes, image frames 540-1 (N−2), 540-2 (N−1), 540-3 (N), 540-4 (N+1), and 540-5 (N+2) may represent a portion of a total image frame captured by the camera 114 for one second. For example, a frame rate of the camera 114 is 50 frames per second. In this example, the illustrated five image frames 540 are representative of a portion of the 50 image frames that were captured by the camera 114 in one second. In some embodiments, the controller 111 may set the timing and duration of the UV light in synchrony with a capture of a particular image frame by the camera 114. For example, the image frames 540-1 (N−2), 540-2 (N−1), 540-3 (N), 540-4 (N+1), and 540-5 (N+2) are the first five frames of the 50 total image frames captured by the camera 114 at a particular time instant. In this example, the timing of the UV light can be synchronized with the timing and duration of the third image frame 540-3 (N) such that only the third image frame 540-3 (N) from the total 50 image frames is selected and further processed to determine the presence of the leak 225.

Following the example above, the controller 111 may compare the selected image frame 540-3 (N) with the adjacent image frames 540-1 (N−2), 540-2 (N−1), 540-4 (N+1), and 540-5 (N+2) that were not exposed to the UV light. Here, any detection of a fluorescent color on the image frames 540-1 (N−2), 540-2 (N−1), 540-4 (N+1), and 540-5 (N+2) may be treated as unwanted signals or can indicate a tampered image frame. For example, the leaked coolant mixture that is detected on the image frames 540-1 (N−2), 540-2 (N−1), 540-4 (N+1), and 540-5 (N+2) may be rejected and flagged as tampered image frames.

In some embodiments, the controller 111 may set the timing and duration of the UV light to be different (i.e., not in sync) from the timing of the frame rate of the camera 114. Here, the controller 111 may set the duration of the illumination to be at least two times the size of an image frame at the particular frame rate so as to capture at least one whole image of the scene or object (not shown). For example, the controller 111 may set the duration of illumination to include at least twice the size of the image frame 540-1 (N−2). Here, and although the firing of the UV light is not synchronized with the capturing of images at a particular frame rate of the camera 114, the controller 111 may still receive and process at least one whole image to detect the fluorescent color.

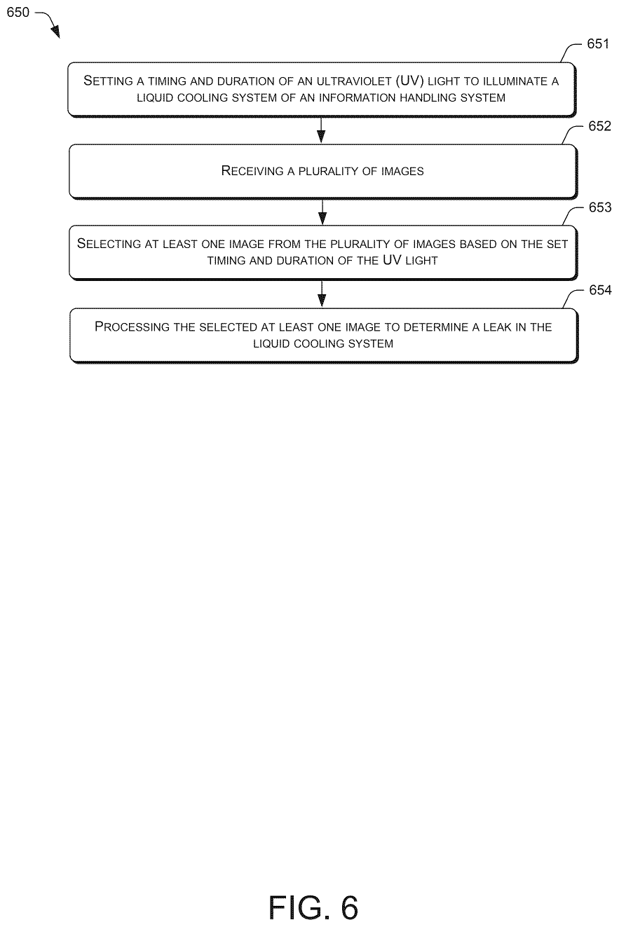

FIG. 6 is a flow diagram of a method 650 for using a camera to determine a leak in the liquid cooling system and components of the information handling system according to at least one embodiment of the present disclosure, starting at step 651. It will be readily appreciated that not every method step set forth in this flow diagram is always necessary, and that certain steps of the methods may be combined, performed simultaneously, in a different order, or perhaps omitted, without varying from the scope of the disclosure. FIG. 1 or 2 may be employed in whole, or in part, by a controller or processor 111 of the information handling system 100 of FIG. 1 or 2, or any other type of controller, device, module, processor, or any combination thereof, operable to employ all, or portions of, the method of FIG. 6.

At step 651, the processor and/or controller may set a timing and duration of a UV light to illuminate a liquid cooling system of the information handling system. In an embodiment, the controller 111 may synchronize the timing of UV illumination with the timing of capturing images by the camera 114. For example, the timing of UV illumination is synchronized with a particular frame rate of the camera 114. In this example, the duration of the UV illumination is at least equal to one frame for the given particular frame rate of the camera 114.

In other embodiments, the timing of UV illumination is asynchronous with the timing of capturing images by the camera 114 at a particular frame rate. Here, controller 111 configures the duration of the UV illumination to be at least twice the size of the image frame that the camera captures at the particular frame rate. When the duration of the asynchronous UV illumination is at least twice the size of the frame rate at the particular frame rate, the controller 111 may be able to process one image frame that is captured during the UV illumination.

At step 652, the processor and/or controller may receive a plurality of images from a camera.

At step 653, the processor and/or controller may select at least one image from the plurality of images based on the set timing and duration of the UV light. For example, the selected at least one image includes one whole image that the camera captured during the duration of the UV illumination.

At step 654, the processor and/or controller may process the selected at least one image to determine a leak in the liquid cooling system. For example, the processing may include stretching the selected at least one image to a rectilinear grid. The stretched image is then blurred and down-sampled. Thereafter, the processor and/or controller may apply a threshold to the down-sampled image to generate a binary image. The binary image may represent an isolated and magnified fluorescent color that indicates the presence of the leak.

In an embodiment, the processor and/or controller may compare the selected at least one image with the adjacent unlit image frames to detect the leak. Here, if fluorescent color appears in both lit and unlit image frames, then the received images are detected to be tampered with a laser pointer, for example.

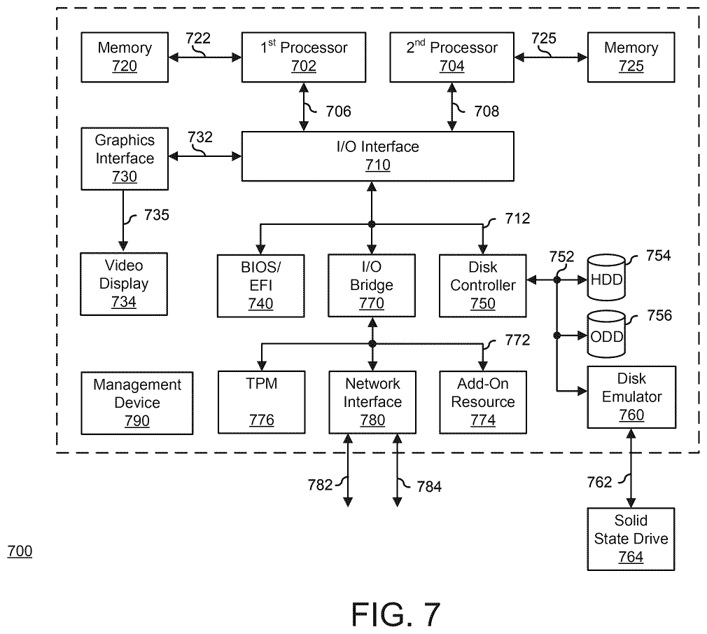

FIG. 7 shows a generalized embodiment of an information handling system 700 according to an embodiment of the present disclosure. Information handling system 700 may be substantially similar to information handling system 100 of FIG. 1. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 700 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 700 can include processing resources for executing machine-executable code, such as a central processing unit (CPU), a programmable logic array (PLA), an embedded device such as a System-on-a-Chip (SoC), or other control logic hardware. Information handling system 700 can also include one or more computer-readable medium for storing machine-executable code, such as software or data. Additional components of information handling system 700 can include one or more storage devices that can store machine-executable code, one or more communications ports for communicating with external devices, and various input and output (I/O) devices, such as a keyboard, a mouse, and a video display. Information handling system 700 can also include one or more buses operable to transmit information between the various hardware components.

Information handling system 700 can include devices or modules that embody one or more of the devices or modules described below and operate to perform one or more of the methods described below. Information handling system 700 includes a processors 702 and 704, an input/output (I/O) interface 710, memories 720 and 725, a graphics interface 730, a basic input and output system/universal extensible firmware interface (BIOS/UEFI) module 740, a disk controller 750, a hard disk drive (HDD) 754, an optical disk drive (ODD) 756, a disk emulator 760 connected to an external solid state drive (SSD) 764, an I/O bridge 770, one or more add-on resources 774, a trusted platform module (TPM) 776, a network interface 780, a management device 790, and a power supply 795. Processors 702 and 704, I/O interface 710, memory 720, graphics interface 730, BIOS/UEFI module 740, disk controller 750, HDD 754, ODD 756, disk emulator 760, SSD 764, I/O bridge 770, add-on resources 774, TPM 776, and network interface 780 operate together to provide a host environment of information handling system 700 that operates to provide the data processing functionality of the information handling system. The host environment operates to execute machine-executable code, including platform BIOS/UEFI code, device firmware, operating system code, applications, programs, and the like, to perform the data processing tasks associated with information handling system 700.

In the host environment, processor 702 is connected to I/O interface 710 via processor interface 706, and processor 704 is connected to the I/O interface via processor interface 708.

Memory 720 is connected to processor 702 via a memory interface 722. Memory 725 is connected to processor 704 via a memory interface 727. Graphics interface 730 is connected to I/O interface 710 via a graphics interface 732 and provides a video display output 736 to a video display 734. In a particular embodiment, information handling system 700 includes separate memories that are dedicated to each of processors 702 and 704 via separate memory interfaces. An example of memories 720 and 730 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 740, disk controller 750, and I/O bridge 770 are connected to I/O interface 710 via an I/O channel 712. An example of I/O channel 712 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 710 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 740 includes BIOS/UEFI code operable to detect resources within information handling system 700, to provide drivers for the resources, initialize the resources, and access the resources. BIOS/UEFI module 740 includes code that operates to detect resources within information handling system 700, to provide drivers for the resources, to initialize the resources, and to access the resources.

Disk controller 750 includes a disk interface 752 that connects the disk controller to HDD 754, to ODD 756, and to disk emulator 760. An example of disk interface 752 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 760 permits SSD 764 to be connected to information handling system 700 via an external interface 762. An example of external interface 762 includes a USB interface, an IEEE 4394 (Firewire) interface, a proprietary interface, or a combination thereof. Alternatively, solid-state drive 764 can be disposed within information handling system 700.

I/O bridge 770 includes a peripheral interface 772 that connects the I/O bridge to add-on resource 774, to TPM 776, and to network interface 780. Peripheral interface 772 can be the same type of interface as I/O channel 712 or can be a different type of interface. As such, I/O bridge 770 extends the capacity of I/O channel 712 when peripheral interface 772 and the I/O channel are of the same type, and the I/O bridge translates information from a format suitable to the I/O channel to a format suitable to the peripheral channel 772 when they are of a different type. Add-on resource 774 can include a data storage system, an additional graphics interface, a network interface card (NIC), a sound/video processing card, another add-on resource, or a combination thereof. Add-on resource 774 can be on a main circuit board, on separate circuit board or add-in card disposed within information handling system 700, a device that is external to the information handling system, or a combination thereof.

Network interface 780 represents a NIC disposed within information handling system 700, on a main circuit board of the information handling system, integrated onto another component such as I/O interface 710, in another suitable location, or a combination thereof.

Network interface device 780 includes network channels 782 and 784 that provide interfaces to devices that are external to information handling system 700. In a particular embodiment, network channels 782 and 784 are of a different type than peripheral channel 772 and network interface 780 translates information from a format suitable to the peripheral channel to a format suitable to external devices. An example of network channels 782 and 784 includes InfiniBand channels, Fibre Channel channels, Gigabit Ethernet channels, proprietary channel architectures, or a combination thereof. Network channels 782 and 784 can be connected to external network resources (not illustrated). The network resource can include another information handling system, a data storage system, another network, a grid management system, another suitable resource, or a combination thereof.

Management device 790 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 700. In particular, management device 790 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 700, such as system cooling fans and power supplies. Management device 790 can include a network connection to an external management system, and the management device can communicate with the management system to report status information for information handling system 700, to receive BIOS/UEFI or system firmware updates, or to perform other task for managing and controlling the operation of information handling system 700.

Management device 790 can operate off of a separate power plane from the components of the host environment so that the management device receives power to manage information handling system 700 when the information handling system is otherwise shut down. An example of management device 790 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 790 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A coolant detection system comprising:
a memory; and
a controller coupled to the memory, the controller configured to:
set a timing and duration of an ultraviolet (UV) light to illuminate a liquid cooling system of an information handling system;
receive from a camera a plurality of images of the liquid cooling system of an information handling system;
select at least one image from the plurality of images based on the set timing and duration of the UV light; and
process the selected at least one image to determine a leak in the liquid cooling system.

2. The coolant detection system of claim 1, wherein the timing for illuminating the images is synchronized with a capture of the images by the camera at a particular frame rate.

3. The coolant detection system of claim 1, wherein the controller utilizes the duration of the UV light to select the at least one image from the plurality of images.

4. The coolant detection system of claim 1, the controller is configured to process the selected at least one image, wherein the controller is further configured to:
stretch the selected at least one image to a rectilinear grid;
blur and down-sample the stretched at least one image;
apply a threshold on the down-sampled at least one image to generate a binary image;
determine the leak from the binary image.

5. The coolant detection system of claim 4, wherein the controller utilizes fluorescent based - fiducial markers as references to stretch the selected at least one image to the rectilinear grid.

6. The coolant detection system of claim 1, the controller is configured to process the selected at least one image, wherein the controller is further configured to:
mask fluorescent based—fiducial markers after the stretching of the selected at least one image to the rectilinear grid.

7. The coolant detection system of claim 1, wherein the selected at least one image includes an image frame that is exposed to the UV light during capture.

8. The coolant detection system of claim 1, wherein the memory stores preconfigured locations of fluorescent based—fiducial markers that are used as references in stretching the selected at least one image to a rectilinear grid.

9. The coolant detection system of claim 8, wherein the controller utilizes the preconfigured locations for masking of the fluorescent based—fiducial markers.

10. The coolant detection system of claim 1, wherein the liquid cooling system utilizes a coolant mixture that emits light at a particular wavelength when exposed to the UV light.

11. A method comprising:
setting a timing and duration of an ultraviolet (UV) light to illuminate a liquid cooling system of an information handling system;
receiving from a camera a plurality of images of the liquid cooling system of an information handling system;
selecting at least one image from the plurality of images based on the set timing and duration of the UV light; and
processing the selected at least one image to determine a leak in the liquid cooling system.

12. The method of claim 11, wherein the timing for illuminating the images is synchronized with a capture of the images by the camera at a particular frame rate.

13. The method of claim 11 further comprising: utilizing the duration of the UV light to select the at least one image from the plurality of images.

14. The method of claim 11, wherein the processing further comprises:
stretching the selected at least one image to a rectilinear grid;
blurring and down-sampling the stretched at least one image;
applying a threshold on the down-sampled at least one image to generate a binary image;
determining the leak from the binary image.

15. The method of claim 14 further comprising: using fluorescent based - fiducial markers as references for stretching the selected at least one image to the rectilinear grid.

16. The method of claim 11, wherein the processing further comprises:
masking fluorescent based—fiducial markers after the stretching of the selected at least one image to the rectilinear grid.

17. The method of claim 11, wherein the selected at least one image includes an image frame that was exposed to the UV light during capture.

18. An information handling system comprising:
a plurality of components;
a liquid cooling system; and
a coolant detection system further comprising:
a memory; and
a controller coupled to the memory, the controller configured to:
set a timing for illuminating with an ultraviolet (UV) light the liquid cooling system and the plurality of components;
receive from a camera a plurality of images of the liquid cooling system and the plurality of components;
select at least one image from the plurality of images based on the set timing of the illumination; and
process the selected at least one image to determine a leak in the liquid cooling system.

19. The information handling system of claim 18, wherein the controller utilizes the duration of the UV light to select the at least one image from the plurality of images.

20. The information handling system of claim 18, the controller is configured to process the selected at least one image, wherein the controller is further configured to:
stretch the selected at least one image to a rectilinear grid;
blur and down-sample the stretched at least one image;
apply a threshold on the down-sampled at least one image to generate a binary image; and
determine the leak from the binary image.
